(19) United States
(12) Patent Application Publication
(10) Pub. No.: US 2020/0365755 A1
(43) Pub. Date: Nov. 19, 2020

(54) SURFACE PASSIVATION OF III-V OPTOELECTRONIC DEVICES

(71) Applicant: ALTA DEVICES, INC., Sunnyvale, CA (US)

(72) Inventors: Andrew J. RITENOUR, San Jose, CA (US); Brendan M. KAYES, Los Gatos, CA (US)

(21) Appl. No.: 15/931,513

(22) Filed: May 13, 2020

Related U.S. Application Data
(60) Provisional application No. 62/847,766, filed on May 14, 2019.

(51) Int. Cl. H01L 31/18; H01L 31/0352

(52) U.S. Cl. CPC H01L 31/1868; H01L 31/0304; H01L 31/1892; H01L 31/0352

(57) ABSTRACT

Aspects of the disclosure relate to surface passivation, and more particularly, surface passivation of optoelectronic devices made of Group III-V semiconductors. In one implementation, a method for passivating an optoelectronic device is described that includes providing a window layer of the optoelectronic device; and depositing a window passivation layer over a surface of the window layer. In another implementation, an optoelectronic device is described that includes a window layer disposed over an absorber layer; and a window passivation layer disposed over a surface of the window layer. In other implementations, a method and an optoelectronic device are based on providing a window layer of the optoelectronic device; and providing a window passivation layer of the optoelectronic device, wherein the window passivation layer is adjacent to the window layer.

### CROSS REFERENCE TO RELATED APPLICATION(S)

This application claims the benefit of U.S. Provisional Application No. 62/847,766, entitled “SURFACE PASSIVATION OF III-V OPTOELECTRONIC DEVICES” and filed on May 14, 2019, which is expressly incorporated by reference herein in its entirety.

### BACKGROUND OF THE DISCLOSURE

Implementations of the disclosure generally relate to surface passivation, and more particularly, surface passivation of optoelectronic devices made of Group III-V semiconductors.

Since the emergence of III-V semiconductors (also referred to as III-V materials, Group III-V semiconductors, Group III-V materials, or simply III-Vs), their implementation in electronic devices (e.g., optoelectronic devices) has been impeded by the lack of a dielectric film with low interfacial defect density. In III-V solar cells or photovoltaics, the quantum efficiency (QE) of λ<400 nm photons is limited by the high surface recombination velocity of the front window.^{1 2} The purpose of the window layer is to block minority carriers inside the absorber (or base) from reaching the defective surface and recombining. Although carriers in the ¹Kayes, B. M. et al. 27.6% Conversion efficiency, a new record for single-junction solar cells under 1 sun illumination. Conf. Rec. IEEE Photovolt. Spec. Conf. 000004-000008 (2011). doi:10.1109/PVSC.2011.6185831²Hwang, S. T. et al. Bandgap grading and Al0.3Ga0.7As heterojunction emitter for highly efficient GaAs-based solar cells. Sol. Energy Mater. Sol. Cells 155, 264-272 (2016). 041223.00541 (0130NP)

absorber are blocked by the window from recombining at the surface, carriers absorbed in the window are likely to recombine since there is no barrier to prevent them from recombining at the front surface.^{3 4 5} As a result, photons which are absorbed inside the absorber (mostly λ>400 nm) typically have high QE while photons absorbed inside the window (mostly λ<400 nm) have lower QE. In order to minimize recombination in the window, III-V solar cells typically use AlInP or AlInGaP because they possess the highest bandgap or energy gap (E_{g}) among lattice-matched III-Vs and consequently absorb relatively weakly in the visible region. For photons λ<400 nm, however, window absorption is strong and QE is low.

Therefore, there is a need for techniques that improve the overall performance for photons λ<400 nm.

### SUMMARY OF THE DISCLOSURE

Implementations of the disclosure generally relate to surface passivation, and more particularly, surface passivation of optoelectronic devices made of Group III-V semiconductors.

In one implementation, a method for passivating an optoelectronic device is described that includes providing a window layer of the optoelectronic device; and depositing a window passivation layer over a surface of the window layer. ³Tsai, C.-D. & Lee, C.-T. Passivation mechanism analysis of sulfur-passivated InGaP surfaces using x-ray photoelectron spectroscopy. J. Appl. Phys. 87, 4230 (2000).

L6 ⁴Yuan, Z. L. et al. Investigation of neutralized, NH 4 . . . 2 S solution passivation of GaAs. 100 . . . surfaces. 71, 3081-3083 (1997). ⁵Robertson, J., Guo, Y. & Lin, L. Defect state passivation at III-V oxide interfaces for complementary metal-oxide-semiconductor devices. J. Appl. Phys. 117, 112806 (2015).

In another implementation, an optoelectronic device is described that includes a window layer disposed over an absorber layer; and a window passivation layer disposed over a surface of the window layer.

In another implementation, a method for passivating an optoelectronic device is described that includes providing a window layer of the optoelectronic device; and providing a window passivation layer of the optoelectronic device, wherein the window passivation layer is adjacent to the window layer.

In another implementation, an optoelectronic device is described that includes a window layer disposed over an absorber layer; and a window passivation layer disposed adjacent to the window layer.

### BRIEF DESCRIPTION OF THE DRAWINGS

So that the manner in which the above recited features of the disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates an example of how the front window passivates GaAs but there is no passivation of the front window.

FIG. 2 illustrates examples of chalcogenides that could be used to passivated the front window, in accordance with aspects of this disclosure.

FIG. 3 illustrates simulations that show how structures in which the front window is passivated may increase external quantum efficiency (EQE), in accordance with aspects of this disclosure.

FIGS. 4A and 4B respectively illustrate examples of the front window not being passivated and the front window being passivated in accordance with aspects of this disclosure.

FIGS. 5A and 5B respectively illustrates examples of structures with the front window not being passivated and the front window being passivate, in accordance with aspects of this disclosure.

FIG. 6 illustrates a method of passivating the front window, in accordance with aspects of this disclosure.

FIG. 7 illustrates another method of passivating the front window, in accordance with aspects of this disclosure.

### DETAILED DESCRIPTION

The following description is presented to enable one of ordinary skill in the art to make and use the disclosure and is provided in the context of a patent application and its requirements. Various modifications to the preferred implementations and the generic principles and features described herein will be readily apparent to those skilled in the art. Thus, the present disclosure is not intended to be limited to the implementations shown, but is to be accorded the widest scope consistent with the principles and features described herein.

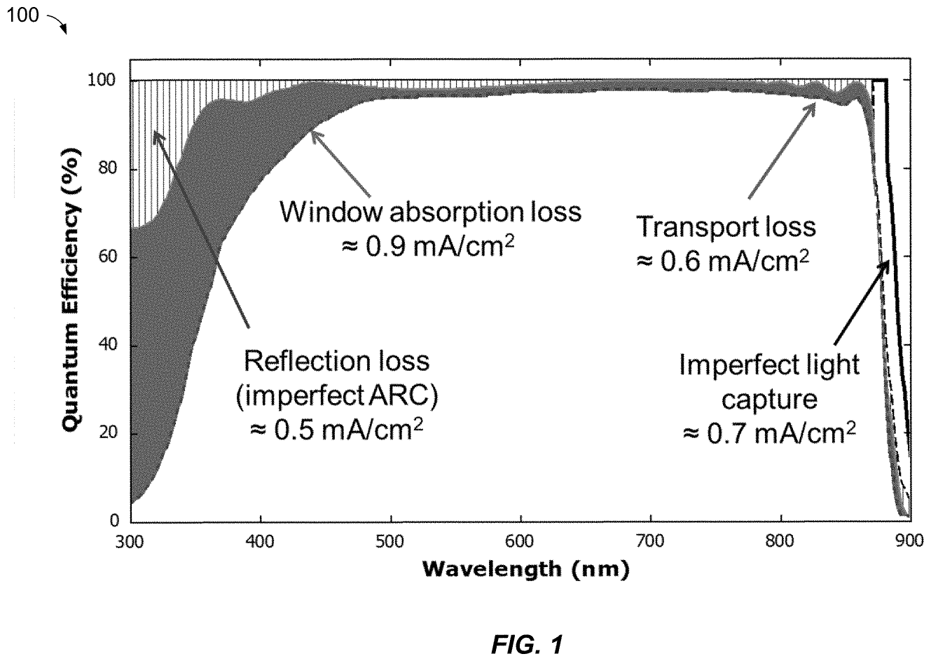

As shown in diagram 100 in FIG. 1, short-circuit current density (J_{sc}) of a some solar cells based on Group III-V semiconductors (e.g., from Alta Devices, Inc.), may be reduced by approximately 0.9 mA/cm² due to window absorption loss, at least for the reasons described above. To put this in perspective, if all of that current were collected rather than lost, leading to a 0.9 mA/cm² boost in J_{sc}, and if that boost came without any penalty to fill factor (FF) or open-circuit voltage (V_{oc}), the 29.1% hero efficiency result⁶ achieved by Alta Device's solar cells could be boosted to approximately 30.0%. Even more importantly, a production-friendly process could enable similarly-significant efficiency improvements. ⁶Green, M. A. et al., Solar cell efficiency tables (Version 53), Prog Photo volt Res Appl. 27, 3-12 (2019).

A higher E_{g} layer which passivates the window layer (and could be thought of as a window for the window) could improve QE for λ<400 nm photons by blocking them from reaching the surface, thus lowering surface recombination and improving device efficiency. Such a layer has not yet been demonstrated. Requirements for a hypothetical ideal window passivation layer (henceforth WPL) include one or more of: large E_{g} (>3 eV) for optical transparency, minimal defects at the window/WPL interface, valence band potential at least 100 mV more negative than that of the valence band of AlInP (so as to prevent minority-carrier holes generated within the window layer from reaching the front surface of the WPL), optical index appropriate for ARC (n=2.2˜2.5), and <200° C. processing for compatibility with polymer-supported solar cells or photovoltaics.

Atomic Layer Deposition (ALD) is a promising technique for the development of dielectric films with low interfacial density of states, a key structure for the future progress of III-V technologies. ALD films are grown at low temperatures (as low as ambient temp) conformally, with high transparency, with nanometer-scale thickness control, and have been shown to reduce surface density of states in III-V materials by cleaning the surface in-situ.^{5 7} Compared to liquid-processed passivation solutions (e.g. ammonium sulfide, sodium sulfide, etc) ALD layers of oxides and sulfides are relatively stable over time when exposed to oxygen and illumination.^{8 9} ⁷Hinkle, C. L. et al. GaAs interfacial self-cleaning by atomic layer deposition. Appl. Phys. Lett. 92, 71901 (2008).⁸Bessolov, V. N. & Lebedev, M. V. Chalcogenide passivation of III-V semiconductor surfaces. Semiconductors 32, 1141-1156 (1998).⁹Wu, D. et al. Temperature studies of sulfur passivated GaAs (100) contacts. Mater. Sci. Eng. B 46, 61-64 (1997).

ALD passivation of III-Vs is an active area of research in the metal-oxide semiconductor field-effect transistor/high electron mobility transistor (MOSFET/HEMT) community, and to a lesser degree in the III-V solar or photovoltaic community. ALD films on III-V materials have been demonstrated to lower metal contact resistance without alloying,^{5 10} decrease surface density of states,¹¹ and improve PL yield.¹² These improvements are understood to be the result of (1) prevention of metal atom diffusion into the epi-layer which lead to defects including metal-induced gap states (MIGS) which act as recombination centers^{5 10} and (2) formation of an interface with a smaller number of defects than the native surface through termination of the crystal, particularly with M₂O₃ layers which can terminate the {100} face of a zincblende crystal without violating the 8-electron counting rules and (3) charge trapped in the non-stoichiometric ALD layers ¹⁰Hu, J., Nainani, A., Sun, Y., Saraswat, K. C. & Philip Wong, H. S. Impact of fixed charge on metal-insulator-semiconductor barrier height reduction. Appl. Phys. Lett. 99, 3-6 (2011).¹¹Xuan, Y., Lin, H. C. & Ye, P. D. Simplified surface preparation for GaAs passivation using atomic layer-deposited high-K dielectrics. IEEE Trans. Electron Devices 54, 1811-1817 (2007).¹²Guziewicz, E. et al. Atomic layer deposition of thin films of ZnSe—Structural and optical characterization. Thin Solid Films 446, 172-177 (2004).

which create a dipole at the surface of the semiconductor, causing the front surface to go into accumulation rather than depletion.¹⁰

ALD deposition cleans III-V substrates and produces interfaces with low interfacial defect density, especially when combined with a NH4OH pretreatment.^{5 7} The NH₄OH removes metal ions, organics, and etches the native oxide leaving a hydrophilic surface. The first pulse of an ALD deposition on III-V is typically the metalorganic precursor, e.g. Al(CH₃)₃ (TMA). Metalorganics like TMA react strongly with any sub-oxides or defects on the surface, as has been demonstrated by XPS.⁷ Thin dielectric layers also provide a diffusion barrier against MIGS and other atoms which can disrupt the interface potential.

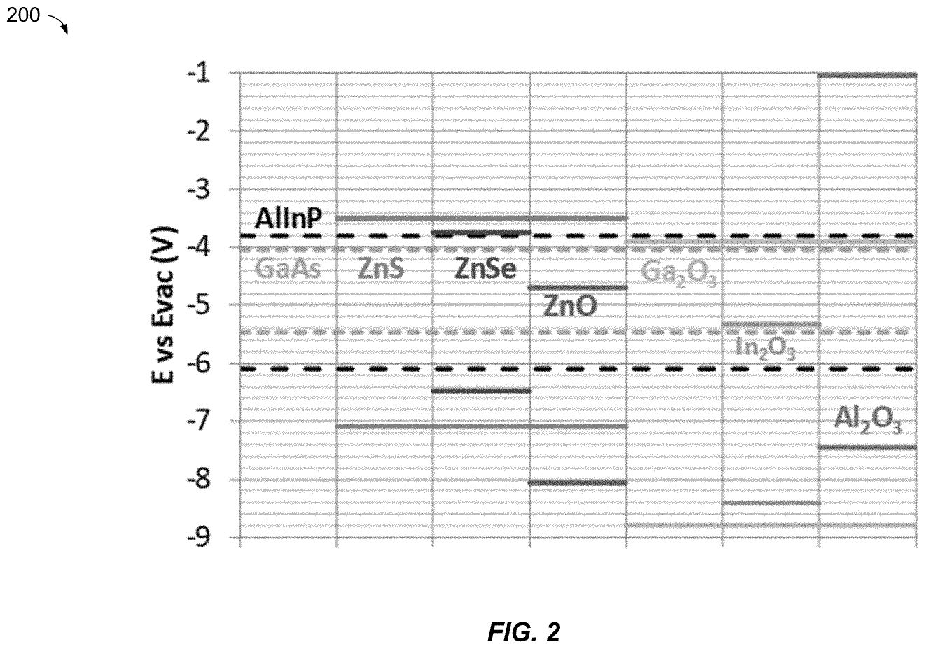

There are several wide-E_{g} materials which have been deposited by ALD and which possess valence band (VB) energies lower than the VB energy of AlInP (se e.g., diagram 200 in FIG. 2). In addition to binary chalcogenides like Ga₂O₃, ZnS and ZnSe, we consider ternary chalcogenides such as ZnSₓO₁₋ₓ, ZnSeₓS₁₋ₓ, and GaₓIn₁₋ₓO₃ which are of additional value for their flexibility owing to their tunable composition and bulk properties. ZnSe has the additional advantage of being approximately lattice-matched to GaAs. There are of course other materials with VB energy lower than the VB energy of AlInP, but it is logical to consider first those materials which have been deposited by ALD, have known bulk properties, and show promise for the application before developing entirely new materials systems.

In general, this disclosure proposes the use of various WPL candidate materials to passivate the window material. Metrics such as improved photoluminescence (PL) of test samples made of the front window material, and improved EQE of full solar cells, may be used to evaluate the WPL candidate materials. The WPL may be deposited by ALD or evaporation, and may include one or more of indium oxide, gallium oxide, indium gallium oxide, aluminum oxide, zinc sulfide, zinc selenide, zinc telluride, zinc oxide, magnesium oxide, magnesium telluride, zinc oxy-sulfide, zinc selenium-sulfide, zinc magnesium oxide, cadmium sulfide, cadmium zinc sulfide, or derivatives, alloys, or combinations thereof.

In some implementations, the surface of the front window may be characterized, prior to deposition of the WPL, by using techniques one or more techniques (e.g., PL). The interface between the front window and the WPL may be characterized, after deposition of the WPL, by using one or more techniques (e.g., PL).

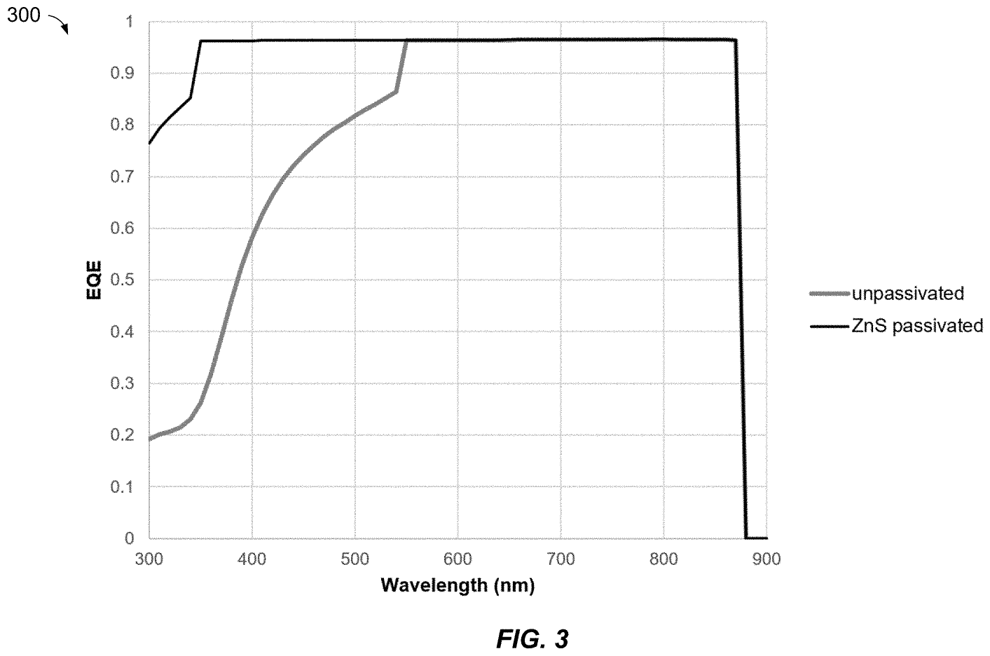

FIG. 3 shows a diagram 300 that illustrates simulations depicting how structures in which the front window is passivated (e.g., by using a WPL based on ZnS) may increase external quantum efficiency (EQE) at lower wavelengths.

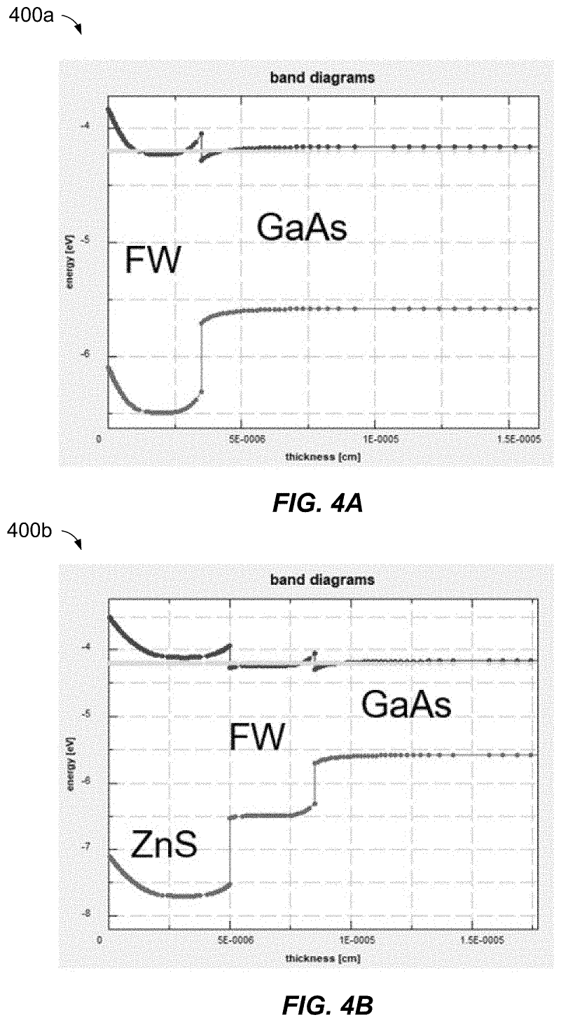

FIGS. 4A and 4B respectively illustrate band diagrams 400a and 400b that show the front window (FW) over a GaAs absorber not being passivated and the front window (FW) over a GaAs absorber being passivated by a WPL based on ZnS.

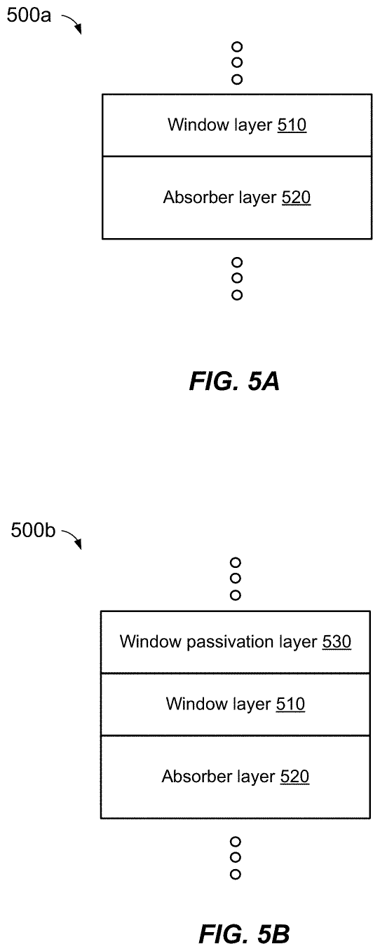

FIGS. 5A and 5B respectively illustrates examples of structures with the front window not being passivated and the front window being passivate, in accordance with aspects of this disclosure. With respect to a front window without passivation, diagram 500a in FIG. 5A shows the structure illustrated in the band diagram 400a in FIG. 4A. In this structure, there is a window layer 510 disposed over an absorber layer 520 (e.g., a Group III-V semiconductor-based layer such as a GaAs-based layer). There may be other layers disposed above the window layer 510 and/or below the absorber layer 520 as part of the overall optoelectronic device (e.g., photovoltaic device).

The window layer 510 may be a group III-V semiconductor, such as AllnP, AlInGaP, InGaP, or AlGaAs, or derivatives, alloys, or combinations thereof. The window layer may have a larger bandgap than the absorber layer. The absorber layer may also be a group III-V semiconductor, such as GaAs, InGaP, AlGaAs, InGaAs, InGaAsP, or derivatives, alloys, or combinations thereof.

With respect to a front window with passivation, diagram 500b in FIG. 5A shows the structure illustrated in the band diagram 400b in FIG. 4B. In this structure, there is a window layer 510 disposed over an absorber layer 520 (e.g., a Group III-V semiconductor-based layer such as a GaAs-based layer) as well as a window passivation layer (WPL) 530 disposed over the window layer 510. There may be other layers disposed above the window passivation layer 530 and/or below the absorber layer 520 as part of the overall optoelectronic device (e.g., photovoltaic device).

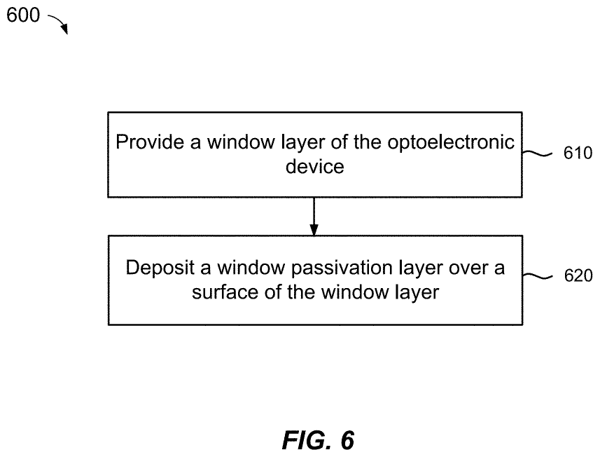

FIG. 6 illustrates a method 600 of passivating the front window (e.g., the window layer 510), in accordance with aspects of this disclosure.

At 610, the method 600 includes providing a window layer (e.g., the window layer 510) of the optoelectronic device.

At 620, the method 600 includes depositing a window passivation layer (e.g., the window passivation layer 530) over a surface of the window layer.

In another aspect of the method 600, the depositing is performed using an atomic layer deposition (ALD) process or an evaporation process.

In another aspect of the method 600, the window layer is deposited over an absorber layer (e.g., the absorber layer 520) of the optoelectronic device. The absorber layer may include one or more Group III-V semiconductors.

In another aspect of the method 600, the window passivation layer includes may include one or more of indium oxide, gallium oxide, indium gallium oxide, aluminum oxide, zinc sulfide, zinc selenide, zinc oxide, zinc oxy-sulfide, zinc selenium-sulfide, zinc magnesium oxide, cadmium sulfide, cadmium zinc sulfide, zinc telluride, magnesium oxide, magnesium telluride, or derivatives, alloys, or combinations thereof.

In another aspect of the method 600, the window passivation layer includes one or more Group II-VI semiconductors.

In another aspect of the method 600, the window passivation layer includes one or more metal oxides.

In another aspect of the method 600, the window passivation layer includes one or more binary chalcogenides, or one or more ternary chalcogenides.

In another aspect of the method 600, the method 600 further includes cleaning the surface of the window layer prior to the deposition of the window passivation layer. The cleaning may be a chemical cleaning that used one or more of ammonium fluoride, ammonium hydroxide, ammonium sulfide, or sodium sulfide.

In another aspect of the method 600, the optoelectronic device is a photovoltaic device such as a solar cell. There may be instances in which the optoelectronic device is a light emitting device such as a light emitting diode (LED), for example.

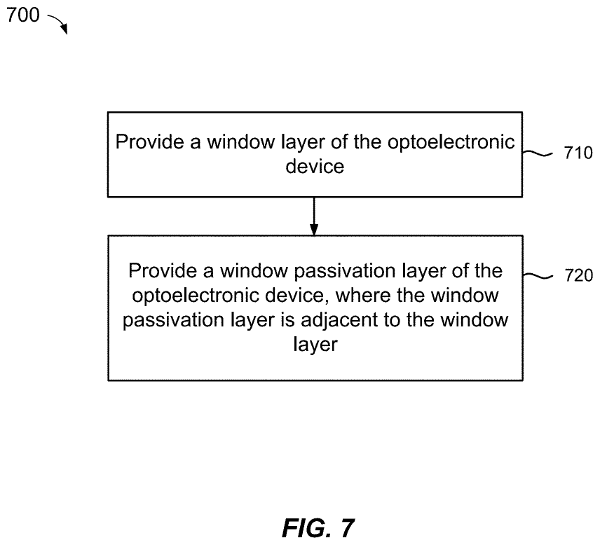

FIG. 7 illustrates a method 700 of passivating the front window (e.g., the window layer 510), in accordance with aspects of this disclosure.

At 710, the method 700 includes providing a window layer of the optoelectronic device.

At 720, the method 700 includes providing a window passivation layer of the optoelectronic device, wherein the window passivation layer is adjacent to the window layer.

In another aspect of the method 700, the window layer may be provided before the window passivation layer.

In another aspect of the method 700, the window passivation layer is provided before the window layer.

In another aspect of the method 700, the method 700 may involve first providing the window layer and then providing the window passivation layer adjacent to the window layer, or alternatively, first providing the window passivation layer and then providing the window layer adjacent to the window passivation layer.

In another aspect of the method 700, the window layer includes one or more Group III-V semiconductors.

In another aspect of the method 700, the window passivation layer includes one or more Group II-VI semiconductors.

In another aspect of the method 700, the window passivation layer includes one or more metal oxides.

In another aspect of the method 700, the window layer is provided by growing the window layer on a substrate by metalorganic chemical vapor deposition (MOCVD) or hydride vapor phase epitaxy (HVPE), and the optoelectronic device is lifted from the substrate by epitaxial lift off (ELO), spalling, laser lift off (LLO), sonic lift off (SLO), or substrate etch back (SEB), prior to deposition of the window passivation layer.

In another aspect of the method 700, the window passivation layer is provided by depositing the window passivation layer prior to the window layer, by MOCVD or HVPE, on a growth substrate, and the optoelectronic device is then lifted from its growth substrate by ELO, spalling, LLO, SLO, or SEB.

The method 700 may produce an optoelectronic device in which a window layer is disposed over an absorber layer; and a window passivation layer disposed adjacent to the window layer. The window passivation layer may be disposed between the window layer and the absorber layer. Alternatively, the window passivation layer may be disposed adjacent to a surface of the window layer and the absorber layer is positioned adjacent to an opposite surface of the window layer.

It is possible that the surface of front window may remain pinned, such that the WPL may not be able to completely electronically passivate the front window. One option to mitigate such result is to combine deposition of the WPL with surface cleaning. One approach is wet chemical cleaning prior to deposition of the WPL, e.g. by using one or more of the following: ammonium fluoride, ammonium hydroxide, ammonium sulfide, or sodium sulfide. Another approach is in-situ etch of the front window, for example by atomic layer etching inside an ALD tool.

In another aspect of the invention, the optoelectronic device includes III-V compounds, and is grown by MOCVD or HVPE on a growth substrate. The optoelectronic device may then be lifted from its growth substrate, for example by ELO, spalling, LLO, SLO, or SEB. After that, and possibly after additional fabrication steps have been completed, the window passivation layer may be deposited, for example by atomic layer deposition (ALD), sputtering, evaporation, or chemical vapor deposition (CVD).

In another aspect of the invention, the window passivation layer is deposited prior to the window layer, by MOCVD or HVPE, on a growth substrate. The optoelectronic device may then be lifted from its growth substrate, for example by ELO, spalling, LLO, SLO, or SEB.

After lift off, the optoelectronic device may be physically flexible.

The optoelectronic device may further include a reflective layer, that is located at the back of the device, below the III-V layers, after the lift off process.

While the foregoing is directed to implementations of the disclosure, other and further implementations of the disclosure may be devised without departing from the basic scope thereof, and the scope thereof is determined by the claims that follow.

1. A method for passivating an optoelectronic device, comprising:
providing a window layer of the optoelectronic device; and
depositing a window passivation layer over a surface of the window layer or providing the window passivation layer adjacent to the window layer.

2. The method of claim 1, further comprising at least one of wherein the window layer includes one or more Group III-V semiconductors or wherein the window passivation layer includes one or more Group II-VI semiconductors or wherein the window passivation layer includes one or more Group II-VI semiconductors.

3. (canceled)

4. (canceled)

5. The method of claim 1, wherein when the window passivation is deposited over the surface of the window layer, the depositing is performed using an atomic layer deposition (ALD) process or an evaporation process.

6. The method of claim 1, wherein when the window passivation is deposited over the surface of the window layer, the window layer is deposited over an absorber layer of the optoelectronic device.

7. The method of claim 6, wherein the absorber layer includes one or more Group III-V semiconductors.

8. The method of claim 1, wherein the window passivation layer includes may include one or more of indium oxide, gallium oxide, indium gallium oxide, aluminum oxide, zinc sulfide, zinc selenide, zinc oxide, zinc oxy-sulfide, zinc selenium-sulfide, zinc magnesium oxide, cadmium sulfide, cadmium zinc sulfide, zinc telluride, magnesium oxide, magnesium telluride, or derivatives, alloys, or combinations thereof.

9. The method of claim 1, wherein the window passivation layer includes one or more binary chalcogenides, or one or more ternary chalcogenides.

10. The method of claim 1, further comprising cleaning the surface of the window layer prior to the deposition of the window passivation layer.

11. The method of claim 10, wherein the cleaning is a chemical cleaning that used one or more of ammonium fluoride, ammonium hydroxide, ammonium sulfide, or sodium sulfide.

12. The method of claim 1, wherein the optoelectronic device is a photovoltaic device.

13. The method of claim 1, wherein the window layer is grown on a substrate by metalorganic chemical vapor deposition (MOCVD) or hydride vapor phase epitaxy (HVPE), and the optoelectronic device is lifted from the substrate by epitaxial lift off (ELO), spalling, laser lift off (LLO), sonic lift off (SLO), or substrate etch back (SEB), prior to deposition of the window passivation layer.

14. The method of claim 1, wherein the window passivation layer is deposited prior to the window layer, by metalorganic chemical vapor deposition (MOCVD) or hydride vapor phase epitaxy (HVPE), on a growth substrate, and the optoelectronic device is then lifted from its growth substrate by epitaxial lift off (ELO), spalling, laser lift off (LLO), sonic lift off (SLO), or substrate etch back (SEB).

15. An optoelectronic device, comprising:
a window layer disposed over an absorber layer; and
a window passivation layer disposed over a surface of or adjacent to the window layer.

16. The optoelectronic device of claim 15, further comprising at least one of wherein the window layer includes one or more Group III-V semiconductors, or wherein the window passivation layer includes one or more Group II-VI semiconductors, or wherein the absorber layer includes one or more Group III-V semiconductors.

17. (canceled)

18. (canceled)

19. The optoelectronic device of claim 15, wherein the window passivation layer includes may include one or more of indium oxide, gallium oxide, indium gallium oxide, aluminum oxide, zinc sulfide, zinc selenide, zinc oxide, zinc oxy-sulfide, zinc selenium-sulfide, zinc magnesium oxide, cadmium sulfide, cadmium zinc sulfide, zinc telluride, magnesium oxide, magnesium telluride, or derivatives, alloys, or combinations thereof.

20. The optoelectronic device of claim 15, wherein the window passivation layer includes one or more binary chalcogenides, or one or more ternary chalcogenides.

21. The optoelectronic device of claim 15, wherein the surface of the window layer is chemically cleaned prior to the disposing of the window passivation layer over the surface of the window layer.

22. The optoelectronic device of claim 15, wherein the optoelectronic device is a photovoltaic device.

23. (canceled)

24. The method of claim 1, wherein when the window passivation layer is adjacent to the window layer, the window layer is provided before the window passivation layer.

25. The method of claim 1, wherein when the window passivation layer is adjacent to the window layer, the window passivation layer is provided before the window layer.

26. (canceled)

27. (canceled)

28. (canceled)

29. The method of claim 1, wherein when the window passivation layer is adjacent to the window layer, he window layer is provided by growing the window layer on a substrate by metalorganic chemical vapor deposition (MOCVD) or hydride vapor phase epitaxy (HVPE), and the optoelectronic device is lifted from the substrate by epitaxial lift off (ELO), spalling, laser lift off (LLO), sonic lift off (SLO), or substrate etch back (SEB), prior to deposition of the window passivation layer.

30. (canceled)

31. (canceled)

32. The optoelectronic device of claim 15, wherein when the window passivation layer is disposed adjacent to the window layer, the window passivation layer is disposed between the window layer and the absorber layer..

33. The optoelectronic device of claim 15, wherein when the window passivation layer is disposed adjacent to the window layer, the window passivation layer is disposed adjacent to a surface of the window layer and the absorber layer is positioned adjacent to an opposite surface of the window layer.

34. (canceled)

35. (canceled)

36. (canceled)
